(19) United States
(12) Patent Application Publication
(10) Pub. No.: US 2026/0354252 A1
(43) Pub. Date: Nov. 5, 2026

(54) ELECTRONIC DEVICE

(71) Applicant: DENSO CORPORATION, Kariya-city (JP)

(72) Inventors: Shunji KUNII, Kariya-city (JP); Noboru NAGASE, Kariya-city (JP); Atsushi SAITO, Kariya-city (JP)

(21) Appl. No.: 19/707,624

(22) Filed: Jun. 15, 2026

Related U.S. Application Data
(63) Continuation of application No. PCT/JP2024/044558, filed on Dec. 17, 2024.

(30) Foreign Application Priority Data
Dec. 18, 2023 (JP) 2023-212724

(51) Int. Cl. H10W 74/10; H02P 25/22; H02P 27/06; H10D 80/30; H10W 40/20; H10W 70/40; H10W 70/60; H10W 72/60; H10W 90/00; H10W 90/10; H10W 90/24

(52) U.S. Cl. CPC H10W 74/114; H02P 25/22; H02P 27/06; H10D 80/30; H10W 40/235; H10W 70/424; H10W 70/479; H10W 70/611; H10W 72/634; H10W 72/642; H10W 72/647; H10W 90/10; H10W 90/24; H10W 90/762; H10W 90/766; H10W 90/753

(57) ABSTRACT

An electronic device includes a plurality of high-side chips, a plurality of low-side chips, a sealing part sealing the high-side chips and the low-side chips, and a plurality of terminals disposed along an outer peripheral portion of the sealing part. The terminals include a power supply terminal, a ground terminal, a signal terminal, and a plurality of output terminals connected to the high-side chips and the low-side chips. The output terminals are disposed at a first side of the sealing part, and the signal terminal is disposed at a second side of the sealing part opposite to the first side. Each of the power supply terminal and the ground terminal is disposed at a lateral side of the sealing part on a lateral side relative to the first side.

### CROSS REFERENCE TO RELATED APPLICATIONS

The present application is a continuation application of International Patent Application No. PCT/JP2024/044558 filed on Dec. 17, 2024, which designated the U.S. and claims the benefit of priority from Japanese Patent Application No. 2023-212724 filed on Dec. 18, 2023. The entire disclosures of all of the above applications are incorporated herein by reference.

### TECHNICAL FIELD

The present disclosure relates to an electronic device.

### BACKGROUND

Conventionally, a semiconductor device in which a semiconductor element is sealed is known. In such a semiconductor device, for example, a semiconductor chip incorporating a power transistor for a high-side switch, a semiconductor chip incorporating a power transistor for a low-side switch, and a semiconductor chip incorporating a control circuit are sealed by a sealing part.

### SUMMARY

According to an aspect of the present disclosure, an electronic device may include: a plurality of high-side chips each including an upper arm element connected on a high potential side; a plurality of low-side chips respectively connected to the plurality of high-side chips to form a plurality of pairs in a module and each of the plurality of low-side chips including a lower arm element disposed on a low potential side relative to the upper arm element of a corresponding high-side chip; a sealing part sealing the plurality of high-side chips and the plurality of low-side chips; and a plurality of terminals including a power supply terminal, a ground terminal, a signal terminal, and a plurality of output terminals connected to the plurality of high-side chips and the plurality of low-side chips, and being disposed along an outer peripheral portion of the sealing part. The output terminals may be disposed at a first side of the sealing part. The signal terminal may be disposed at a second side of the sealing part opposite to the first side. Each of the power supply terminal and the ground terminal may be disposed at a lateral side of the sealing part on a lateral side relative to the first side. One of the plurality of high-side chips and one of the plurality of low-side chips forming a pair may be stacked such that the low-side chip is disposed on a top surface side of the high-side chip and shifted such that a portion of a top surface of the high-side chip is not overlapped by the low-side chip.

### BRIEF DESCRIPTION OF THE DRAWINGS

Objects, features, and advantages of the present disclosure will become more apparent from the following detailed description with reference to the accompanying drawings, in which:

FIG. 1 is a plan view of an electronic device according to a first embodiment;

FIG. 2 is a cross-sectional view of the electronic device taken along a line II-II of FIG. 1;

FIG. 3 is a circuit diagram of the electronic device according to the first embodiment;

FIG. 4 is an explanatory diagram for explaining a parasitic inductor;

FIG. 5 is a plan view of an electronic device according to a second embodiment;

FIG. 6 is a plan view of an electronic device according to a third embodiment and

FIG. 7 is a cross-sectional view of an electronic device according to another embodiment.

### DETAILED DESCRIPTION

In a semiconductor device in which a semiconductor chip for a high-side switch and a semiconductor chip for a low-side switch are arranged on opposite faces of a semiconductor chip incorporating a control circuit, it is necessary to arrange a wiring connecting a high-side element and a low-side element outside the semiconductor device. For example, when the high-side element and the low-side element are connected on a substrate, a power wiring through which a relatively large current flows and a signal wiring for control are present in a mixed manner, which may increase noise and surge, causing a malfunction. Moreover, if the wiring connecting the high-side element and the low-side element is disposed on the substrate, it is difficult to reduce a physical size, and it is difficult to draw out the signal wiring.

The present disclosure provides an electronic device capable of reducing noise and surge.

An electronic device according to a first aspect of the present disclosure includes a plurality of high-side chips, a plurality of low-side chips, a control chip, and a sealing part. An electronic device according to a second aspect of the present disclosure includes a plurality of high-side chips, a plurality of low-side chips, a sealing part and a plurality of terminals.

The high-side chip includes an upper arm element connected to a high potential side. The low-side chip includes a lower arm element connected to a low potential side of a corresponding upper arm element, and is connected to the high-side chip to form a pair in a module.

In the first aspect, the control chip includes a pre-driver integrated circuit configured to output drive signals for the upper arm element and the lower arm element. The sealing part seals the high-side chips, the low-side chips, and the control chip. The high-side chips and the low-side chips are disposed in an area adjacent to one side of the control chip with gate electrodes facing the control chip. In the control chip, connection positions of signal lines connected to the high-side chips or the low-side chips are disposed along the one side adjacent to the area in which the high-side chips and the low-side chips are disposed.

In the second aspect, the sealing part seals the high-side chips and the low-side chips. The terminals include a power supply terminal, a ground terminal, a signal terminal, and output terminals connected to the high-side chips and the low-side chips, and are disposed along an outer peripheral portion of the sealing part. The output terminals are disposed at a first side of the sealing part, and the signal terminal is disposed at a second side of the sealing part opposite to the first side. The power supply terminal and the ground terminal are disposed at a lateral side of the sealing part on a lateral side relative to the first side. Thus, it is possible to consolidate a region where a relatively large current is applied, suppressing occurrence of noise and surge.

Hereinafter, multiple embodiments of the present disclosure will be described with reference to the drawings. In the multiple embodiments described hereinafter, substantially identical configurations are denoted by the same reference numerals, and the description thereof will not be repeated.

### First Embodiment

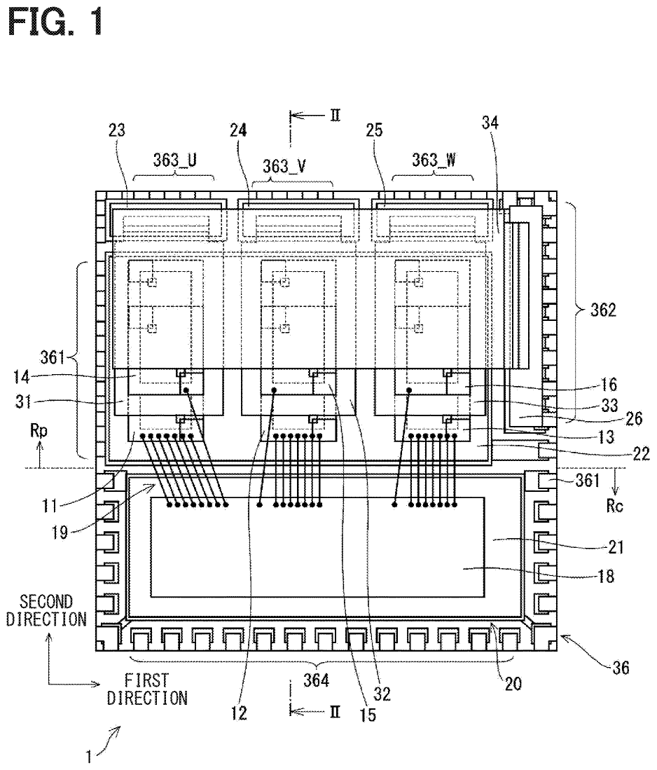

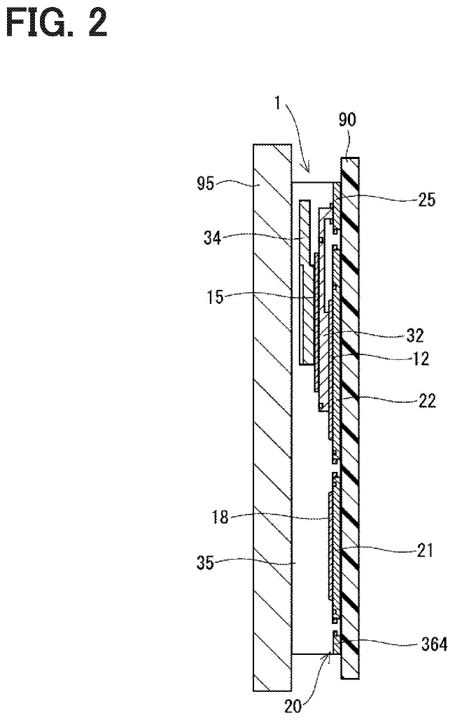

A first embodiment is shown in FIGS. 1 to 3. As shown in FIGS. 1 and 2, an electronic device 1 includes high-side chips 11 to 13, low-side chips 14 to 16, a control chip 18, a lead frame 20, clips 31 to 34, a sealing part 35, and the like. The chips 11 to 16 and 18, the lead frame 20, and the clips 31 to 34 are integrally sealed by t he sealing part 35 so that the electronic device 1 has a substantially rectangular shape in a plan view as a whole, and heat can be dissipated to a heat dissipation portion 95 disposed on a top surface side. For the sake of description, illustration of the sealing part 35 is omitted in FIG. 1 and the like, and hatching of the sealing part 35 is omitted in FIG. 2.

Terminals 36 are disposed at an outer peripheral portion of the sealing part 35. The terminals 36 may be of a non-lead type, or may be a lead type in which a lead protrudes. The terminals 36 include a power supply terminal 361, a ground terminal 362, an output terminal 363, and a signal terminal 364. In the drawings, the reference numeral of the output terminal 363 is indicated with a sign of a corresponding phase in such a manner as “363_U”. in a control region Rc, terminals disposed at lateral sides can be used as the signal terminal 364. However, among the terminals connected to a control land 21, a terminal arranged adjacent to a boundary with a power region Rp is assigned to a power supply terminal or a ground terminal related to power feeding to a pre-driver integrated circuit (IC) 180.

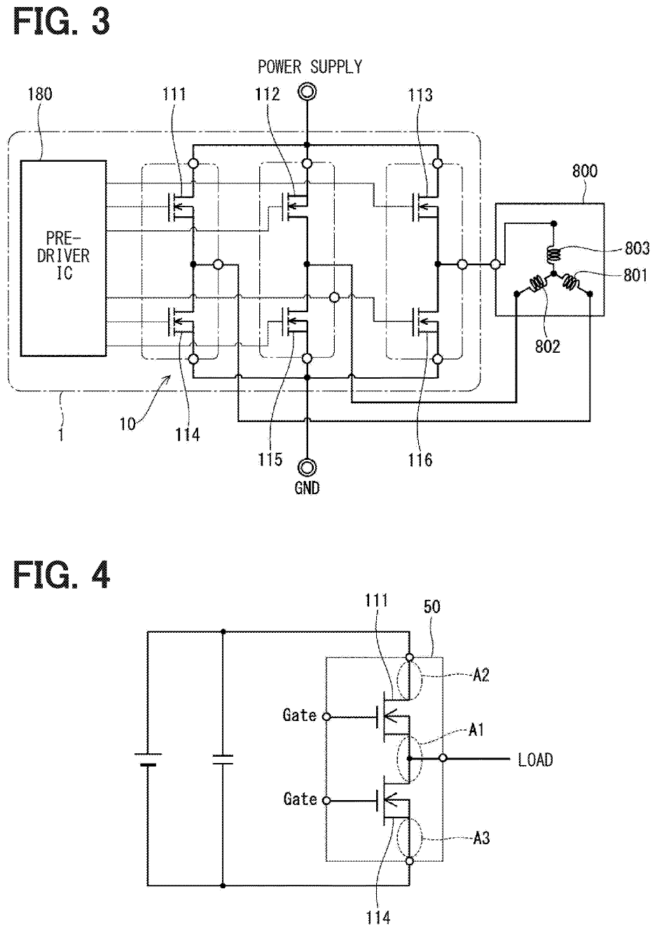

The high-side chips 11 to 13 incorporate upper arm elements 111 to 113, and the low-side chips 14 to 16 incorporate lower arm elements 114 to 116 (see FIG. 3). The upper arm elements 111 to 113 and the lower arm elements 114 to 116 of the present embodiment are metal oxide semiconductor field effect transistors (MOSFETs), but may be insulated gate bipolar transistors (IGBTs), bipolar transistors, or the like. Each of the high-side chips 11 to 13 and the low-side chips 14 to 16 has a source electrode on a top surface side thereof and a drain electrode on a back surface side thereof. The high-side chips 11 to 13 and the low-side chips 14 to 16 are connected to the control chip 18 through signal lines 19. The signal lines 19 include a signal line for gate driving, a signal line for current detection, a signal line for temperature detection, and the like.

As shown in FIG. 3, the upper arm elements 111 to 113 and the lower arm elements 114 to 116, which are six switching elements, are bridge-connected to constitute a driver circuit 10 for driving a motor 800 as a load. Drains of the upper arm elements 111 to 113 are connected to a power supply, and sources of the upper arm elements 111 to 113 are connected to drains of the lower arm elements 114 to 116, which are correspondingly provided. Sources of the lower arm elements 114 to 116 are connected to a ground. Gates of the upper arm elements 111 to 113 and the lower arm elements 114 to 116 are connected to the pre-driver IC 180 incorporated in the control chip 18.

A connection point between the upper arm element 111 and the lower arm element 114, which are paired and provided for a U phase, is connected to one end of a motor winding 801 of the U phase. A connection point between the upper arm element 112 and the lower arm element 115, which are paired and provided for a V phase, is connected to one end of a motor winding 802 of the V phase. A connection point between the upper arm element 113 and the lower arm element 116, which are paired and provided for a W phase, is connected to one end of a motor winding 803 of the W phase. The other ends of the motor windings 801 to 803 are wired together. The connection of the motor windings 801 to 803 is not limited to a Y-connection, and may be a Δ-connection.

Returning to FIGS. 1 and 2, the lead frame 20 includes lands 21 to 26. A back surface of the lead frame 20 is exposed from the sealing part 35, and is electrically connected to a wiring pattern of a substrate 90 by solder bonding or the like. Note that it is not always necessary that all the lands are connected to the substrate 90 on a back surface side. Each of the lands 21 to 26 is formed integrally with the terminal 36 or is connected to the terminal 36 at a side of the outer peripheral portion of the sealing part 35. The control chip 18 is placed on a control land 21, and the high-side chips 11 to 13 are placed on a power land 22.

The control chip 18 has a substantially rectangular shape in a plan view. Hereinafter, a direction parallel to a long side of the control chip 18 is referred to as a “first direction”, and a direction orthogonal to the first direction, i.e., a direction parallel to a short side of the control chip 18 is referred to as a “second direction”. Further, inside a mold, i.e., in the sealing part 35, a side adjacent to the lead frame 20 will be referred to as a “lower side”, and a side opposite to the lead frame 20 will be referred to as the top surface side or an “upper side”.

The lands 21 to 25 are arranged in an order of the control land 21, the power land 22 and three output lands 23 to 25 from one side (i.e., a bottom side in FIG. 1) in the second direction. A ground land 26 is arranged adjacent to the power land 22 and the output land 25. The control land 21 is at a ground potential, and uses the terminals that are arranged at both the short sides and the long side, which is on a side further from the power land 22, as the signal terminal 364.

The power land 22 is arranged adjacent to a long side of the control land 21. The power land 22 is in contact with a power supply pattern of the substrate 90 on a back surface side, and is at a power supply potential. The power land 22 uses the terminals that are arranged at a side, which is on a side opposite to the ground land 26 in the first direction, as the power supply terminal 361. The high-side chips 11 to 13 are arranged side by side on the power land 22 and are oriented in such a manner that each of the high-side chips 11 to 13 has the source on the upper side, the drain on the lower side and the gate facing the long side of the control chip 18. The drain electrodes of the high-side chips 11 to 13 are connected to the power land 22.

The output lands 23 to 25 are arranged side by side adjacent to the power land 22 on a side opposite to the control land 21. The output terminals 363 are formed at end portions of the output lands 23 to 25 on a side opposite to the power land 22 in the second direction. The output terminals 363 are connected to the motor windings of the respective phases via substrate wirings (not shown) or the like. The ground terminal 362 is formed at an end portion of the ground land 26 on a side opposite to the land 25 in the first direction.

Intermediate clips 31 to 33 are respectively placed on the high-side chips 11 to 13. The intermediate clips 31 to 33 are conductive metal plates, such as copper plates. The intermediate clips 31 to 33 each have a plate shape wider than the corresponding chip 11 to 16. The intermediate clips 31 to 33 are connected to the high-side chips 11 to 13 and the low-side chips 14 to 16 at first ends thereof and to the output lands 23 to 25 at second ends thereof. The intermediate clips 31 to 33 are arranged in such a manner that an edge of the first end of each of the intermediate clips 31 to 33 is shifted from an edge of the corresponding high-side chip 11 to 13 on the control chip 18 side to be away from the control chip 18, thereby enabling the gate electrode of the corresponding high-side chip 11 to 13 to be connected to the control chip 18.

The low-side chips 14 to 16 are arranged on the upper side of the intermediate clips 31 to 33. The low-side chips 14 to 16 are arranged such that the drains are on the lower side, the sources are on the upper side and the gates face the long side of the control chip 18. Thus, the sources of the high-side chips 11 to 13 and the drains of the low-side chips 14 to 16 are connected by the intermediate clips 31 to 33, respectively. The second ends of the intermediate clips 31 to 33 are bent toward the lower side, and are connected to the output lands 23 to 25, respectively.

A ground clip 34 is a conductive plate, such as a copper plate. The ground clip 34 has a plate shape. The ground clip 34 covers the upper sides of the low-side chips 14 to 16. The ground clip 34 is bent toward the lower side at an end portion in the first direction, and is connected to the ground land 26. In FIG. 1, the ground land 26 is arranged on a right side of the power land 22. As another example, the ground land 26 may be arranged on a left side of the power land 22. As further another example, the ground lands 26 may be arranged on both sides of the power land 22 in the first direction. In the case where the ground lands 26 are arranged on both sides of the power land 22 in the first direction, the ground clip 34 is bent toward the lower side at both end portions to be connected to the ground lands 26. The same applies to a ground land 46 of an embodiment to be described later.

In the electronic device 1, the drain electrodes of the high-side chips 11 to 13 are connected by the power land 22, which is a metal plate commonly provided, and the source electrodes of the low-side chips 14 to 16 are connected by the ground clip 34, which is a metal plate commonly provided.

The ground clip 34 is arranged in such a manner that an end portion of the ground clip 34 on the control chip 18 side is shifted from the end portions of the low-side chips 14 to 16 on the control chip 18 side to be away from the control chip 18, thereby enabling the gates of the low-side chips 14 to 16 to be connected to the control chip 18.

The ground clip 34 is formed to be wide so as to cover the upper sides of the bent portions of the second ends of the intermediate clips 31 to 33. By forming the area of the ground clip 34 as large as possible, a heat dissipation efficiency can be enhanced. It is preferable to reduce the thickness of the sealing part 35 on the upper side of the ground clip 34 in terms of the heat dissipation.

In the electronic device 1, the control chip 18 is disposed in an area on one side in the second direction, and the chips 11 to 16 constituting the driver circuit 10 are disposed in an area on the other side. Further, the power region Rp to which a relatively large current is applied and the control region Rc to which a relatively small current is applied are consolidated and arranged in separate regions. In the power region Rp, from the lower side, the power land 22, the high-side chips 11 to 13, the intermediate clips 31 to 33, the low-side chips 14 to 16, and the ground clip 34 are stacked in this order, thereby forming a stacked structure.

Further, the chips 11 to 16 are arranged so that the gate electrodes face the control chip 18, and the power land 22, the high-side chips 11 to 13, the intermediate clips 31 to 33, the low-side chips 14 to 16, and the ground clip 34 are stacked and shifted in a stepped manner so as to enable the connection of the gate electrodes to the control chip 18, so that the chips 11 to 16 each have a non-overlapping region that does not overlap a member stacked on the upper side thereof. Thus, the chips 11 to 16 can be connected to the control chip 18 by wire bonding using the signal lines 19. Further, in the control chip 18, connection positions with the gate electrodes of the chips 11 to 16 are consolidated at one side adjacent to the chips 11 to 16.

In the electronic device 1, in the power region Rp, the power supply terminal 361 is arranged on the one side in the first direction, the ground terminal 362 is arranged on the other side in the first direction. Further, the output terminal 363 is arranged at the end portion in the second direction. Thus, when viewed as a whole, the power supply and the ground are input in the first direction, and the electric power related to motor driving is output in the second direction. As a result, the wiring connecting the power supply and the ground in the power region Rp and the signal line 19 of the control chip 18 can be separated from each other, and an influence of noise or surge can be reduced. In addition, the power land 22 having the power supply potential and the ground land 26 are arranged adjacent to each other. Therefore, a loop of a power portion serving as a noise source becomes small, so that noise can be reduced.

FIG. 4 is an explanatory diagram for explaining a parasitic inductor (hereinafter, “ESL”) in the driver circuit 10. In this case, a U-phase arm will be described as an example. When a large current is applied to the electronic device 1, a magnetic field is generated around the electronic device 1, and a part enclosed by a broken-line circle in FIG. 4 becomes the ESL. Energy accumulated in this part is applied to the element, resulting in a switching loss. For example, as a reference example, in a case where an upper arm element is arranged on one side of a control chip, a lower arm element is arranged on the other side of the control chip, and a source of the upper arm element and a drain of the lower arm element are connected by a substrate wiring outside a module, a wiring length becomes long, so that the ESL becomes large.

In the present embodiment, the sources of the high-side chips 11 to 13 and the drains of the low-side chips 14 to 16 are connected on opposite faces of the intermediate clips 31 to 33. That is, since the wiring length between the drain and the source indicated by A1 in FIG. 4 corresponds to a thickness of the intermediate clips 31 to 33, the wiring length is shorter than that in the case of connecting via the substrate wiring or the like outside the module. Therefore, it is possible to reduce the ESL.

Further, the drains of the upper arm elements 111 to 113 indicated by A2 in FIG. 4 are connected to the power land 22, which are provided commonly for the three phases, and the sources of the lower arm elements 114 to 116 indicated by A3 in FIG. 4 are connected by the ground clip 34, which are provided commonly for the three phases. Therefore, since an ESL difference between the phases is eliminated, switching of freewheeling current becomes fast, and switching loss can be reduced.

The control chip 18 constituting the pre-driver IC 180 is disposed inside the module and the gate signal line is wired inside the module. Since it is not necessary to have vias or the like, as compared to the case where the gate wiring is provided on a printed circuit board, for example, the ESL can be reduced.

As described above, the electronic device 1 includes the plurality of high-side chips 11 to 13, the plurality of low-side chips 14 to 16, the control chip 18, and the sealing part 35. The high-side chips 11 to 13 include the upper arm elements 111 to 113, which are connected to the high potential side. The low-side chips 14 to 16 include the lower arm elements 114 to 116, which are connected to the low potential side of the respective upper arm elements 111 to 113, and are connected to the respective high-side chips 11 to 13 forming pairs inside the module. Specifically, the high-side chip 11 and the low-side chip 14, which form the pair for the U-phase, are connected to each other. The high-side chip 12 and the low-side chip 15, which form the pair for the V-phase, are connected to each other. The high-side chip 13 and the low-side chip 16, which form the pair for the W-phase, are connected to each other.

The control chip 18 includes the pre-driver IC 180 that outputs the drive signals for the upper arm elements 111 to 113 and the lower arm elements 114 to 116. The pre-driver IC 180 has at least a function of a pre-driver. The sealing part 35 seals the high-side chips 11 to 13, the low-side chips 14 to 16, and the control chip 18.

The high-side chips 11 to 13 and the low-side chips 14 to 16 are arrayed adjacent to one long side of the control chip 18 with the gate electrodes to which the drive signals are input facing the control chip 18. In the control chip 18, the connection positions at which the signal lines 19, which are connected to the high-side chips 11 to 13 or the low-side chips 14 to 16, are connected are disposed along the one side adjacent to the area in which the high-side chips 11 to 13 and the low-side chips 14 to 16 are arranged. In this case, it is not necessary that all the signal terminals are arranged on a straight line parallel to the long side, and it is acceptable that the signal terminals may be shifted in some extent due to space reasons or the like, for example. Such shifted arrangement is included in a concept of “disposed along the one side”. By arranging the signal line connection positions of the chips 11 to 16 and the control chip 18 to face each other, the control region Rc and the power region Rp to which a relatively large current is applied can be separated.

The electronic device 1 includes the high-side chips 11 to 13, the low-side chips 14 to 16, the sealing part 35, and the terminals 36. The terminals 36 include the power supply terminal 361, the ground terminal 362, the signal terminal 364, and the output terminals 363 connected to the high-side chips 11 to 13 and the low-side chips 14 to 16. The terminals 36 are disposed along the outer peripheral end of the sealing part 35.

The sealing part 35 has a rectangular shape. The output terminals 363 are disposed at one side of the sealing part 35, and the signal terminal 364 is provided at another side of the sealing part 35, which is opposite to the side on which the output terminals 363 are provided. The power supply terminal 361 and the ground terminal 362 are disposed on lateral sides of the sealing part 35 that are on lateral sides relative to the side on which the output terminals 363 are provided. Note that all terminals at each side may not be assigned to corresponding terminals, and may include an empty terminal. At the lateral sides where the power supply terminal 361 and the ground terminal 362 are disposed, for example, the signal terminal 364 may be provided on a control region Rc side. By providing the output terminal 363 at the side opposite to the signal terminal 364, the control region Rc and the power region Rp can be separated.

Therefore, in the electronic device 1, the occurrence of noise and surge can be suppressed. Further, since the power line through which a relatively large current is applied and the signal line can be separated, a malfunction can be suppressed. Furthermore, substrate wiring becomes easy.

The high-side chips 11 to 13 and the low-side chips 14 to 16 are disposed i the area on one side of the control chip 18 in the second direction. The output terminals 363 are disposed at the side of the sealing part 35, e.g., a first side, which is adjacent to the area where the high-side chips 11 to 13 and the low-side chips 14 to 16 are disposed. The signal terminal 364 is disposed at the opposite side of the sealing part 35, e.g., a second side, which is adjacent to the area where the control chip 18 is provided. Therefore, the control region Rc and the power region Rp can be appropriately separated.

The high-side chips 11 to 13 and the low-side chips 14 to 16, which form pairs, are stacked in a shifted state such that the low-side chips 14 to 16 are on the top surface side and a part of a top surface of the high-side chips 11 to 13 is not covered by the low-side chips 14 to 16. Therefore, a physical size of the electronic device 1 can be reduced. In addition, by stacking the low-side chips 14 to 16 in the shifted manner to secure the non-overlapping region on the top surface side of the high-side chips 11 to 13, the signal line 19 can be appropriately connected.

### Second Embodiment

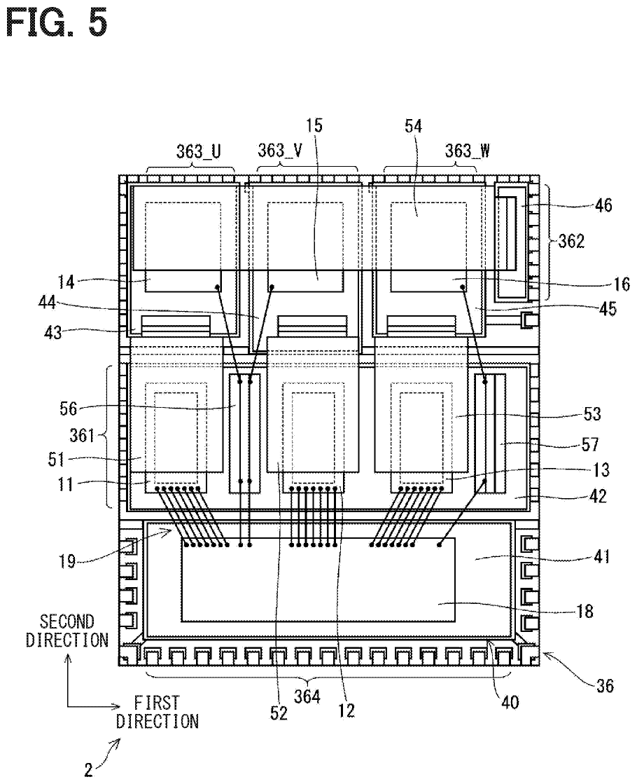

A second embodiment is shown in FIG. 5. An electronic device 2 of the second embodiment includes the high-side chips 11 to 13, the low-side chips 14 to 16, the control chip 18, a lead frame 40, clips 51 to 54, relay substrates 56 and 57, the sealing part 35 (not shown in FIG. 5), and the like. In the present embodiment, the high-side chips 11 to 13 and the low-side chips 14 to 16 are not stacked, and are arranged flatly, that is, arranged side by side on the lead frame 40.

The lead frame 40 includes lands 41 to 46, and each of the lands 41 to 46 is formed integrally with the terminal 36 or is connected to the terminal 36 at a side on an outer peripheral portion of the sealing part 35. A control land 41 is substantially the same as the control land 21 of the first embodiment, and the control chip 18 is arranged on the control land 41.

Similar to the power land 22 of the first embodiment, a power land 42 is at a power supply potential, and is disposed adjacent to the control land 41 so as to face one long side of the control chip 18. Further, the high-side chips 11 to 13 are arranged on the power land 42 and the drain electrodes of the high-side chips 11 to 13 on a back surface side are connected to the power land 42.

Output lands 43 to 45 are arranged side by side along a long side of the power land 42 in an area opposite to the control land 41 in the second direction. The low-side chips 14 to 16 are arranged on the output lands 43 to 45 and the drain electrodes of the low-side chips 14 to 16 on a back surface side are connected to the output lands 43 to 45. The source electrodes on the upper side of the high-side chips 11 to 13 are connected to the output lands 43 to 45 by intermediate clips 51 to 53. The intermediate clips 51 to 53 are substantially the same as the intermediate clips 31 to 33 of the first embodiment except that the low-side chips 14 to 16 are not placed on top surfaces thereof.

A ground clip 54 covers the top surface side of the low-side chips 14 to 16. The ground clip 54 is bent to the lower side at an end in the first direction to be connected to a ground land 46. The ground land 46 is arranged side by side with the output land 45 in the first direction. The clips 51 to 54 are arranged in a shifted manner such that end portions on the control chip 18 side are shifted in a direction away from the control chip 18 so as to enable the gate terminals of the chips 11 to 16 to be connected to the control chip 18.

In the present embodiment, since the chips 11 to 16 are arranged flatly and the high-side chips 11 to 13 are arranged between the low-side chips 14 to 16 and the control chip 18, it is difficult to directly connect the gate electrodes of the low-side chips 14 to 16 and the control chip 18.

Therefore, in the present embodiment, the relay substrates 56 and 57 are disposed on the power land 42, and the gate electrodes of the low-side chips 14 to 16 and the control chip 18 are connected via the relay substrates 56 and 57. The relay substrates 56 and 57 are, for example, printed substrates, ceramic substrates, or the like, and are formed with wiring patterns capable of connecting wires connecting the gate electrodes and the control chip 18. In the present embodiment, the high-side chips 11 to 13 and the relay substrates 56 and 57 are arranged from one side in the first direction in an order of the high-side chip 11, the relay substrate 56, the high-side chips 12 and 13, and the relay substrate 57.

The relay substrate 56 is arranged between the high-side chip 11 and the high-side chip 12. The relay substrate 56 relays the gate electrodes of the low-side chips 14 and 15 and the control chip 18. That is, the relay substrate 56 is shared for relaying the gate electrodes of the low-side chips 14 and 15. The relay substrate 57 is arranged adjacent to the high-side chip 13 on a side opposite to the high-side chip 12, and relays the gate electrode of the low-side chip 16 and the control chip 18. Note that the relay substrates only need to be able to interconnect between the gate electrodes of the low-side chips 14 to 16 and the control chip 18, and the number, shape, arrangement, and the like thereof may be modified.

In the electronic device 2 of the present embodiment, the high-side chips 11 to 13 are arranged side by side along one side of the control chip 18, and the low-side chips 14 to 16 are arranged side by side along the high-side chips 11 to 13 in an area opposite to the control chip 18.

The electronic device 2 includes the relay substrates 56 and 57 that are arranged between the high-side chips 11 to 13 arranged side by side or on a lateral side of the high-side chips 11 to 13. The gate electrodes of the low-side chips 14 to 16 are connected to the control chip 18 via the relay substrates 56, 57. Therefore, even when the chips 11 to 16 are arranged flatly, the control region Rc and the power region Rp can be appropriately separated. Further, the gate electrodes of the low-side chips 14 to 16 arranged spaced apart from the control chip 18 and the control chip 18 can be appropriately connected.

### Third Embodiment

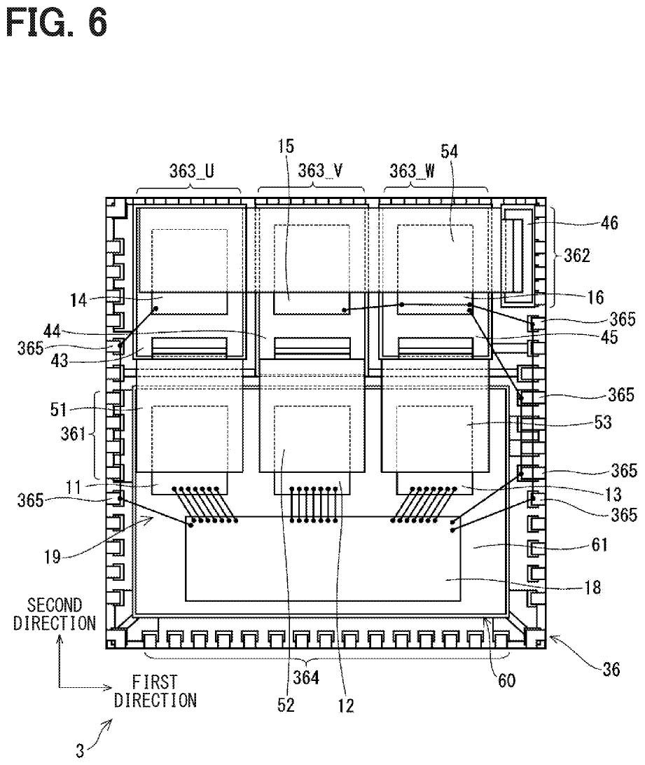

A third embodiment is shown in FIG. 6. An electronic device 3 of the third embodiment includes the high-side chips 11 to 13, the low-side chips 14 to 16, the control chip 18, a lead frame 60, the clips 51 to 54, the sealing part 35 (not shown in FIG. 6), and the like. The lead frame 60 includes lands 43 to 46 and 61. The land 61 is at a power supply potential, and the high-side chips 11 to 13 and the control chip 18 are arranged on the land 61.

In the control chip 18 of the present embodiment, a back surface side of an element is insulated. Therefore, a potential of a land on which the control chip 18 is mounted is not limited to a ground potential, and may be a power supply potential. By using a back surface-insulated chip as the control chip 18 and sharing the land 61 by the high-side chips 11 to 13 and the control chip 18, the electronic device 3 can be reduced in size. Note that, in the first embodiment and the second embodiment, a land may be shared by the high-side chips 11 to 13 and the control chip 18. In the present embodiment, the land may be divided between the high-side chips 11 to 13 and the control chip 18.

In the present embodiment, since the chips 11 to 16 are arranged flatly, similarly to the second embodiment, it is difficult to directly connect the gate electrodes of the low-side chips 14 to 16 and the control chip 18. In the present embodiment, the gate electrodes of the low-side chips 14 to 16 and the control chip 18 are connected via empty terminals 365 to which a power supply potential, a ground potential, or various signals are not assigned.

Specifically, the gate electrode of the low-side chip 14 is connected to the control chip 18 via an empty terminal 365 on a left side in FIG. 6. The gate electrode of the low-side chip 16 is connected to the control chip 18 via an empty terminal 365 on a right side in FIG. 6. The gate electrode of the low-side chip 15 arranged between the low-side chips 14 and 16 is connected to the control chip 18 via a relay pad disposed on the low-side chip 16 and the empty terminal 365 on the right side in FIG. 6. Note that a relay pad may be provided on the low-side chip 14, and the gate electrode of the low-side chip 15 may be configured to be connected to the control chip 18 via an empty terminal on the left side in FIG. 6.

In the electronic device 3 of the present embodiment, similarly to the second embodiment, the chips 11 to 16 are arranged flatly. Further, the gate electrodes of the low-side chips 14 to 16 are connected to the control chip 18 via the empty terminals 365 provided on the lateral sides of the sealing part 35. Even with this configuration, the gate electrodes of the low-side chips 14 to 16 arranged spaced apart from the control chip 18 and the control chip 18 can be appropriately connected.

### Other Embodiments

In the embodiments described above, the low-side chips are connected by the ground clip which is a plate-shaped metal plate. As another embodiment, a member connecting sources of low-potential-side elements is not limited to a metal plate, and ribbon bonding or aluminum bonding may be used. The same applies to a member connecting high-side chips.

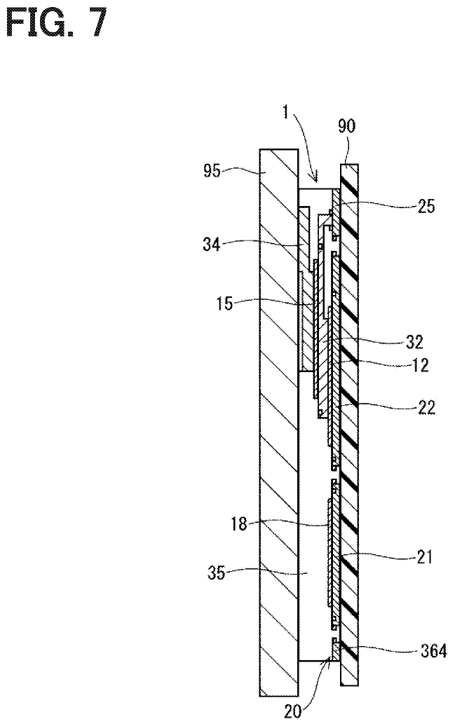

In the embodiments described above, the ground clip 34 is sealed by the sealing part 35. As another embodiment, as shown in FIG. 7, the ground clip 34 may be exposed from the top surface side of the sealing part 35, and heat may be directly dissipated to the heat dissipation portion 95. Thus, a heat dissipation efficiency can be improved. Note that FIG. 7 exemplifies the electronic device 1 of the first embodiment, but the top surface side of the ground clip may be exposed from the sealing part 35 in the second embodiment or the third embodiment.

In the embodiments described above, the driver circuit 10 is a three-phase inverter having three sets of upper and lower arm elements. As another embodiment, the number of arms may be two, or four or more. As described above, the present disclosure is not limited to the embodiments described above in any way, and can be implemented in various forms without departing from the gist thereof.

The present disclosure has been described based on the embodiments. However, the present disclosure is not limited to the embodiments and structures. The present disclosure also encompasses various modifications and modifications within equivalent ranges. In addition, various combinations and forms, and further, other combinations and forms including only one element, or more, or less than that, are also within the scope and technical spirit of the present disclosure.

What is claimed is:

1. An electronic device comprising:
a plurality of high-side chips each including an upper arm element connected to a high potential side;
a plurality of low-side chips respectively connected to the plurality of high-side chips to form a plurality of pairs in a module, the plurality of low-side chips each including a lower arm element disposed on a low potential side relative to the upper arm element of a corresponding high-side chip;
a sealing part sealing the plurality of high-side chips and the plurality of low-side chips; and
a plurality of terminals including a power supply terminal, a ground terminal, a signal terminal, and a plurality of output terminals connected to the plurality of high-side chips and the plurality of low-side chips, the plurality of terminals being disposed along an outer peripheral portion of the sealing part, wherein
the output terminals are disposed at a first side of the sealing part,
the signal terminal is disposed at a second side of the sealing part opposite to the first side,
each of the power supply terminal and the ground terminal is disposed at a lateral side of the sealing part on a lateral side relative to the first side, and
one of the plurality of high-side chips and one of the plurality of low-side chips forming a pair are stacked such that the low-side chip is disposed on a top surface side of the high-side chip and are shifted such that a portion of a top surface of the high-side chip is not overlapped by the low-side chip.

2. The electronic device according to claim 1, further comprising:
a control chip incorporating a pre-driver integrated circuit configured to output drive signals for the upper arm element and the lower arm element, the control chip being sealed in the sealing part, wherein
the plurality of high-side chips and the plurality of low-side chips are disposed in an area on one side of the control chip and adjacent to the first side of the sealing part, and
the control chip is disposed in an area adjacent to the second side of the sealing part.

3. An electronic device comprising:
a plurality of high-side chips each including an upper arm element connected to a high potential side;
a plurality of low-side chips respectively connected to the plurality of high-side chips to form a plurality of pairs in a module, the plurality of low-side chips each including a lower arm element disposed on a low potential side relative to the upper arm element of a corresponding high-side chip;
a sealing part sealing the plurality of high-side chips and the plurality of low-side chips;
a plurality of terminals including a power supply terminal, a ground terminal, a signal terminal, and a plurality of output terminals connected to the plurality of high-side chips and the plurality of low-side chips, the plurality of terminals being disposed along an outer peripheral portion of the sealing part; and
a control chip including a pre-driver integrated circuit configured to output drive signals for the upper arm element and the lower arm element, the control chip being sealed in the sealing part, wherein
the output terminals are disposed at a first side of the sealing part,
the signal terminal is disposed at a second side of the sealing part opposite to the first side,
each of the power supply terminal and the ground terminal is disposed at a lateral side of the sealing part on a lateral side relative to the first side,
the plurality of high-side chips and the plurality of low-side chips are disposed in an area on one side of the control chip and adjacent to the first side of the sealing part,
the control chip is disposed in an area adjacent to the second side of the sealing part,
the plurality of high-side chips are arranged side by side in a lateral direction, the plurality of low-side chips are arranged side by side in the lateral direction, and
the control chip, the plurality of high-side chips and the plurality of low-side chips are arranged in this order along one direction,
the electronic device further comprising:
a relay substrate disposed between the plurality of high-side chips arranged in the lateral direction or on a lateral side of the plurality of high-side chips, wherein
gate electrodes of the plurality of low-side chips to which drive signals are input are connected to the control chip via the relay substrate.

4. An electronic device comprising:
a plurality of high-side chips each including an upper arm element connected to a high potential side;
a plurality of low-side chips respectively connected to the plurality of high-side chips to form a plurality of pairs in a module, the plurality of low-side chips each including a lower arm element disposed on a low potential side relative to the upper arm element of a corresponding high-side chip;
a sealing part sealing the plurality of high-side chips and the plurality of low-side chips;
a plurality of terminals including a power supply terminal, a ground terminal, a signal terminal, and a plurality of output terminals connected to the plurality of high-side chips and the plurality of low-side chips, the plurality of terminals being disposed along an outer peripheral portion of the sealing part; and
a control chip including a pre-driver integrated circuit configured to output drive signals for the upper arm element and the lower arm element, the control chip being sealed in the sealing part, wherein
the output terminals are disposed at a first side of the sealing part,
the signal terminal is disposed at a second side of the sealing part opposite to the first side,
each of the power supply terminal and the ground terminal is disposed at a lateral side of the sealing part on a lateral side relative to the first side,
the plurality of high-side chips and the plurality of low-side chips are disposed in an area on one side of the control chip and adjacent to the first side of the sealing part,
the control chip is disposed in an area adjacent to the second side of the sealing part,
the plurality of high-side chips are arranged side by side in a lateral direction, the plurality of low-side chips are arranged side by side in the lateral direction, and
the control chip, the plurality of high-side chips and the plurality of low-side chips are arranged in this order along one direction,
the electronic device further comprising:
a relay substrate disposed between the plurality of high-side chips arranged in the lateral direction or on a lateral side of the plurality of high-side chips, wherein
gate electrodes of the plurality of low-side chips to which drive signals are input are connected to the control chip via an empty terminal disposed at a lateral side of the sealing part.
